(19) United States
(12) Patent Application Publication
(10) Pub. No.: US 2026/0018964 A1
(43) Pub. Date: Jan. 15, 2026

(54) DRIVE DEVICE

(71) Applicant: DENSO CORPORATION, Kariya-city (JP)

(72) Inventor: Naohiro YAMAMOTO, Kariya-city (JP)

(21) Appl. No.: 19/338,929

(22) Filed: Sep. 24, 2025

Related U.S. Application Data
(63) Continuation of application No. PCT/JP2024/009280, filed on Mar. 11, 2024.

(30) Foreign Application Priority Data
Mar. 30, 2023 (JP) 2023-055577

(51) Int. Cl. H02K 5/22; H05K 1/11; H05K 7/14

(52) U.S. Cl. CPC H02K 5/225; H05K 1/115; H05K 7/1427

(57) ABSTRACT

A drive device includes an electric motor, a frame member, a circuit board, a connector unit and a cover. The connector unit includes: a base portion; a connector portion, which is located on one side of the base portion opposite to the electric motor; a plurality of terminal holding portions, which are formed integrally with the base portion and the connector portion in one-piece and are located on another side of the base portion where the electric motor is placed; and a plurality of connector terminals, which project from the plurality of terminal holding portions. The plurality of connector terminals resiliently contact and are thereby connected to the circuit board. The cover is formed separately from the connector unit. A plurality of load-bearing portions are formed on the frame member and project toward and contact the circuit board.

### CROSS REFERENCE TO RELATED APPLICATIONS

This application is a continuation application of International Patent Application No. PCT/JP2024/009280 filed on Mar. 11, 2024, which designated the U.S. and claims the benefit of priority from Japanese Patent Application No. 2023-055577 filed on Mar. 30, 2023. The entire disclosures of all of the above applications are incorporated herein by reference.

### TECHNICAL FIELD

The present disclosure relates to a drive device.

### BACKGROUND

A previously proposed drive device includes: an electric motor; and a controller which is assembled together with the electric motor to control energization of the electric motor. In the previously proposed drive device, power supply connector terminals and signal connector terminals are press-fit terminals connected to a circuit board by resilient contact of the press-fit terminals against the circuit board.

### SUMMARY

This section provides a general summary of the disclosure, and is not a comprehensive disclosure of its full scope or all of its features.

According to the present disclosure, there is provided a drive device that may include an electric motor, a frame member, a circuit board, a connector unit and a cover. The frame member may be located on one side of the electric motor in an axial direction. The circuit board may be located on one side of the frame member opposite to the electric motor and may be fixed to the frame member. The connector unit may include a base portion, a connector portion, a plurality of terminal holding portions and a plurality of connector terminals. The connector portion may be located on one side of the base portion opposite to the electric motor. The plurality of terminal holding portions may be formed integrally with the base portion and the connector portion in one-piece and may be located on another side of the base portion where the electric motor is placed. The plurality of connector terminals may project from the plurality of terminal holding portions. The plurality of connector terminals may resiliently contact and may be thereby mechanically and electrically connected to the circuit board. The cover may be formed separately from the connector unit and may receive the circuit board and the plurality of connector terminals in a state in which the connector portion is exposed outside the cover. The plurality of load-bearing portions may be formed on the frame member in at least one terminal region where the plurality of connector terminals are connected to the circuit board. The plurality of load-bearing portions may project toward and contact the circuit board.

### BRIEF DESCRIPTION OF DRAWINGS

The drawings described herein are for illustrative purposes only of selected embodiments and not all possible implementations, and are not intended to limit the scope of the present disclosure.

FIG. 1 is a schematic structural diagram showing an electric power steering apparatus according to a first embodiment.

FIG. 2 is a perspective view showing a drive device according to the first embodiment.

FIG. 3 is a plan view showing the drive device according to the first embodiment.

FIG. 4 is a view as seen in a direction of arrow IV in FIG. 3.

FIG. 5 is a view as seen in a direction of arrow V in FIG. 3.

FIG. 6 is a cross-sectional view taken along line VI-VI in FIG. 4.

FIG. 7 is a perspective view showing an ECU according to the first embodiment.

FIG. 8 is a perspective view showing the ECU according to the first embodiment.

FIG. 9 is a plan view showing the ECU according to the first embodiment.

FIG. 10 is a view as seen in a direction of arrow X in FIG. 9.

FIG. 11 is a cross-sectional view taken along line XI-XI in FIG. 9.

FIG. 12 is a view as seen in a direction of arrow XII in FIG. 9.

FIG. 13 is a cross-sectional view taken along line XIII-XIII in FIG. 9.

FIG. 14 is a cross-sectional view showing a modification of a cover.

FIG. 15 is a perspective view showing a frame member according to the first embodiment.

FIG. 16 is a perspective view showing the frame member according to the first embodiment.

FIG. 17 is a plan view showing the frame member according to the first embodiment.

FIG. 18 is a view as seen in a direction of arrow XVIII in FIG. 17.

FIG. 19 is a cross-sectional view taken along line XIX-XIX in FIG. 17.

FIG. 20 is a view as seen in a direction of arrow XX in FIG. 17.

FIG. 21 is a cross-sectional view taken along line XXI-XXI in FIG. 17.

FIG. 22 is a plan view showing a state in which a connector unit is assembled to a circuit board according to the first embodiment.

FIG. 23 is a view as seen in a direction of arrow XXIII in FIG. 22.

FIG. 24 is a cross-sectional view taken along line XXIV-XXIV in FIG. 23.

FIG. 25 is a cross-sectional view taken along line XXV-XXV in FIG. 24.

FIG. 26 is an enlarged view of a portion XXVI in FIG. 25.

FIG. 27 is a perspective view showing a state in which the circuit board is assembled to the frame member according to the first embodiment.

FIG. 28 is a perspective view showing a state in which the connector unit is assembled to the circuit board according to the first embodiment.

FIG. 29 is a plan view showing the frame member according to the first embodiment.

FIG. 30 is a schematic diagram showing a connected state in which a connector terminal is connected to the circuit board according to the first embodiment.

FIG. 31 is a plan view showing a frame member according to a second embodiment.

FIG. 32 is a plan view for explaining a load-bearing portion according to the second embodiment.

FIG. 33 is a plan view for explaining the load-bearing portion according to the second embodiment.

FIG. 34 is a schematic diagram for explaining a terminal arrangement.

FIG. 35 is a plan view for explaining load-bearing portions according to a third embodiment.

FIG. 36 is a plan view for explaining the load-bearing portions according to the third embodiment.

FIG. 37 is a cross-sectional view showing an ECU according to a fourth embodiment.

### DETAILED DESCRIPTION

A previously proposed drive device includes: an electric motor; and a controller which is assembled together with the electric motor to control energization of the electric motor. In the previously proposed drive device, power supply connector terminals and signal connector terminals are press-fit terminals connected to a circuit board by resilient contact of the press-fit terminals against the circuit board.

In the previously proposed drive device, since the connectors are integrated with a cover member, at the time of connecting the connector and the circuit board together, the connectors and the circuit board are assembled in a blind state, in which the connection between the connectors and the circuit board cannot be seen.

A drive device of the present disclosure includes an electric motor, a frame member, a circuit board, a connector unit and a cover. The frame member is located on one side of the electric motor in an axial direction. The circuit board is located on one side of the frame member opposite to the electric motor and is fixed to the frame member.

The connector unit includes: a base portion; a connector portion, which is located on one side of the base portion opposite to the electric motor; a plurality of terminal holding portions, which are formed integrally with the base portion and the connector portion in one-piece and are located on another side of the base portion where the electric motor is placed; and a plurality of connector terminals, which project from the plurality of terminal holding portions. The plurality of connector terminals resiliently contact and are thereby mechanically and electrically connected to the circuit board. The cover is formed separately from the connector unit and receives the circuit board and the plurality of connector terminals in a state in which the connector portion is exposed outside the cover.

The plurality of load-bearing portions are formed on the frame member in at least one terminal region where the plurality of connector terminals are connected to the circuit board, and the plurality of load-bearing portions project toward and contact the circuit board. This makes it possible to properly assemble the connector unit and the circuit board.

Hereinafter, embodiments of the present disclosure will be described with reference to the drawings. In the following description, the same reference signs are given to substantially the same portions among the embodiments, and the redundant description thereof will be omitted for the sake of simplicity.

### First Embodiment

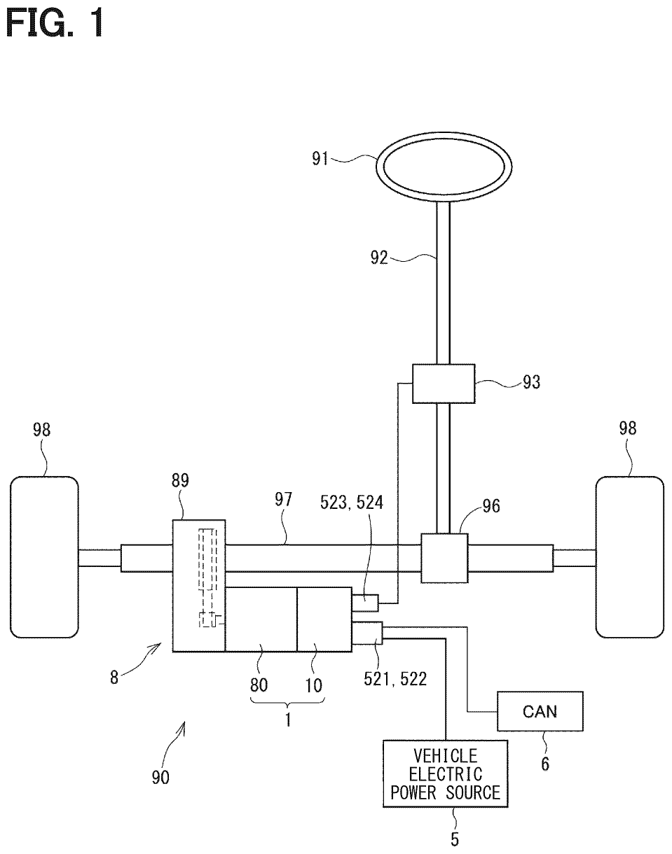

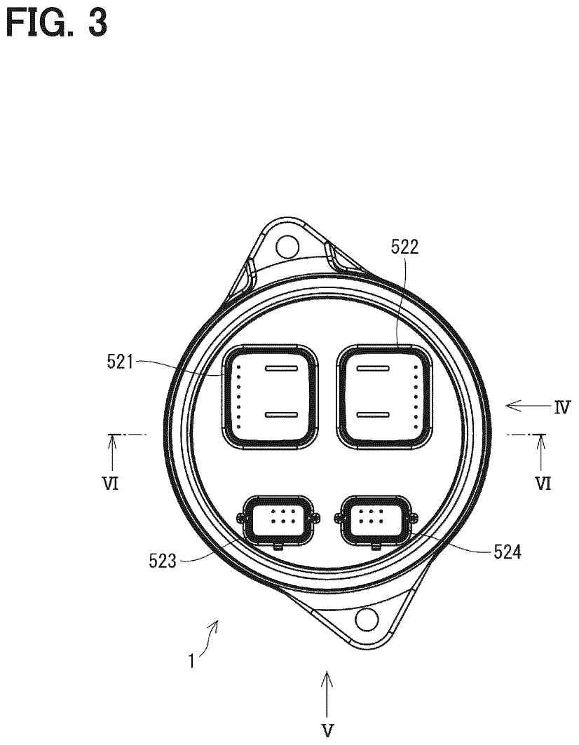

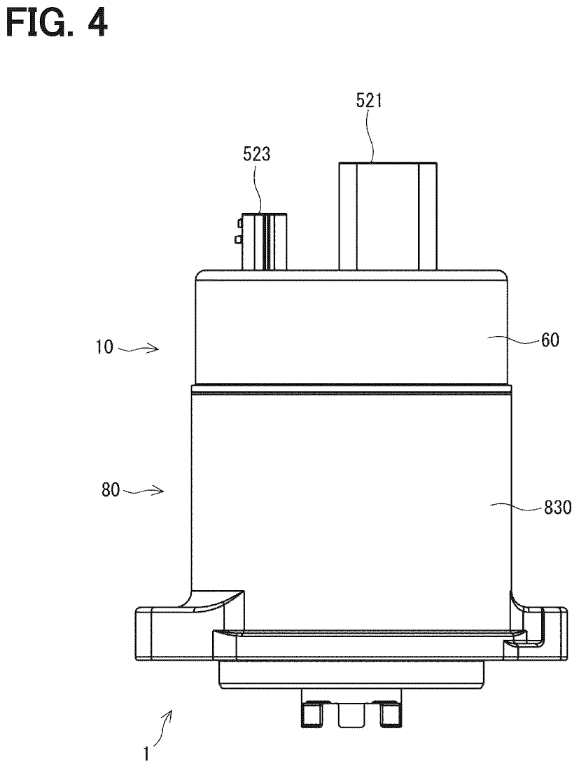

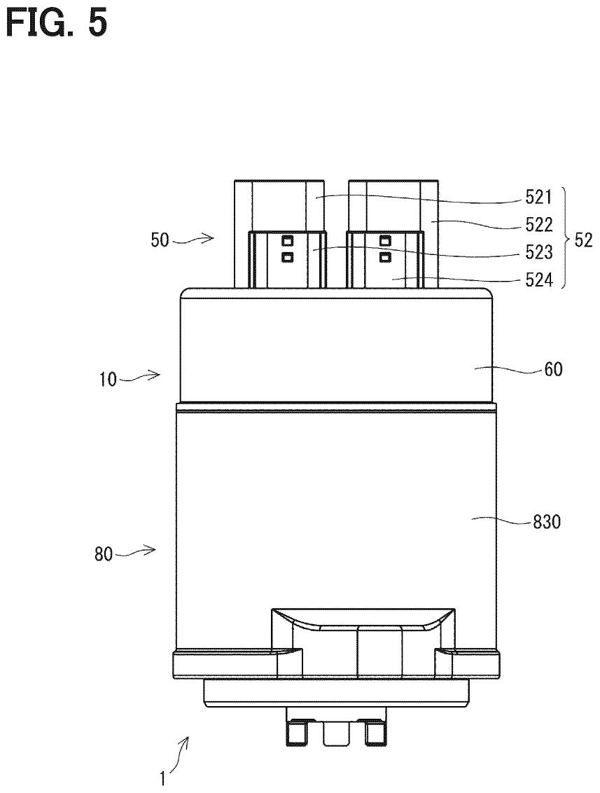

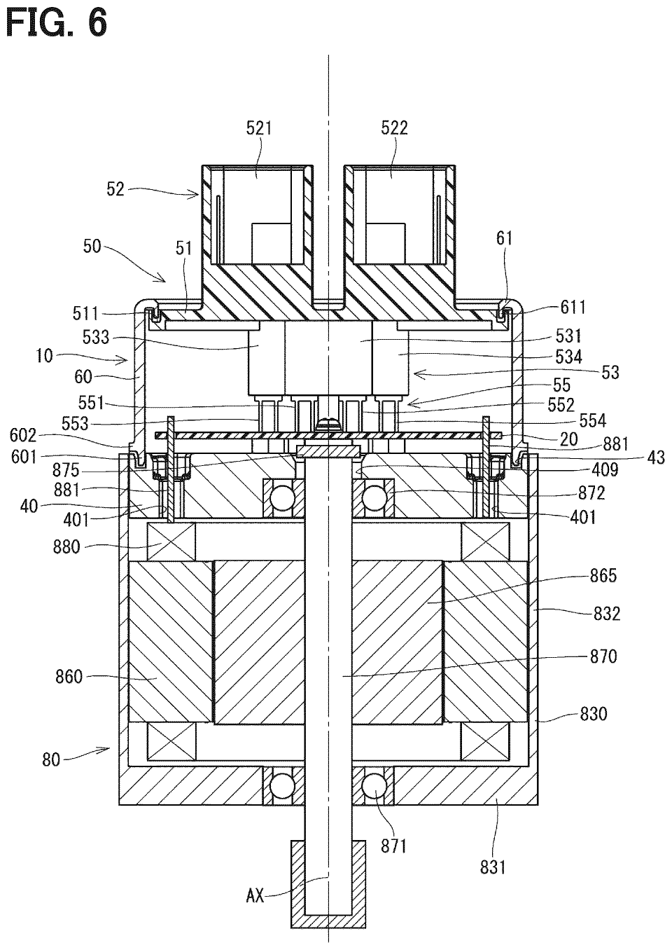

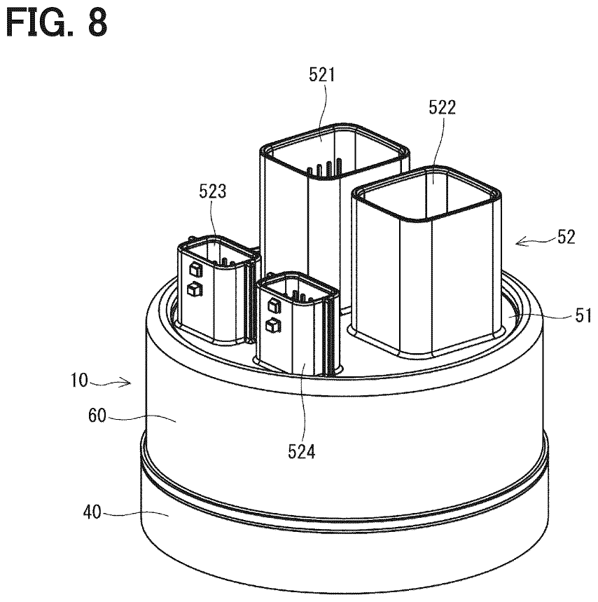

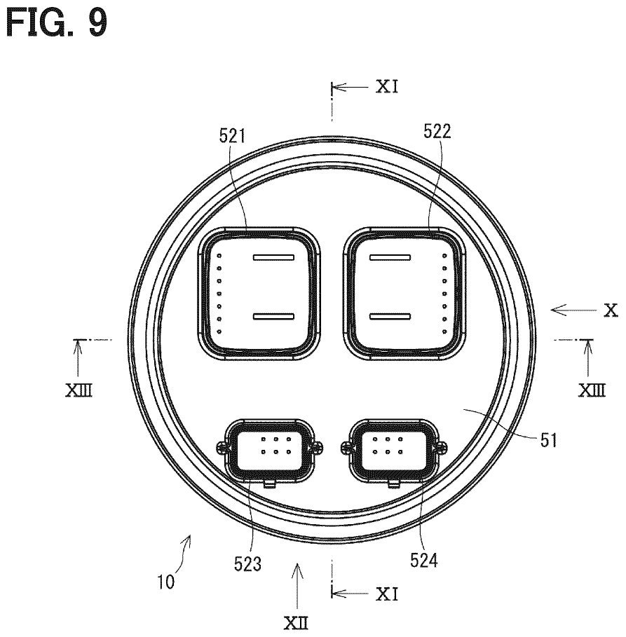

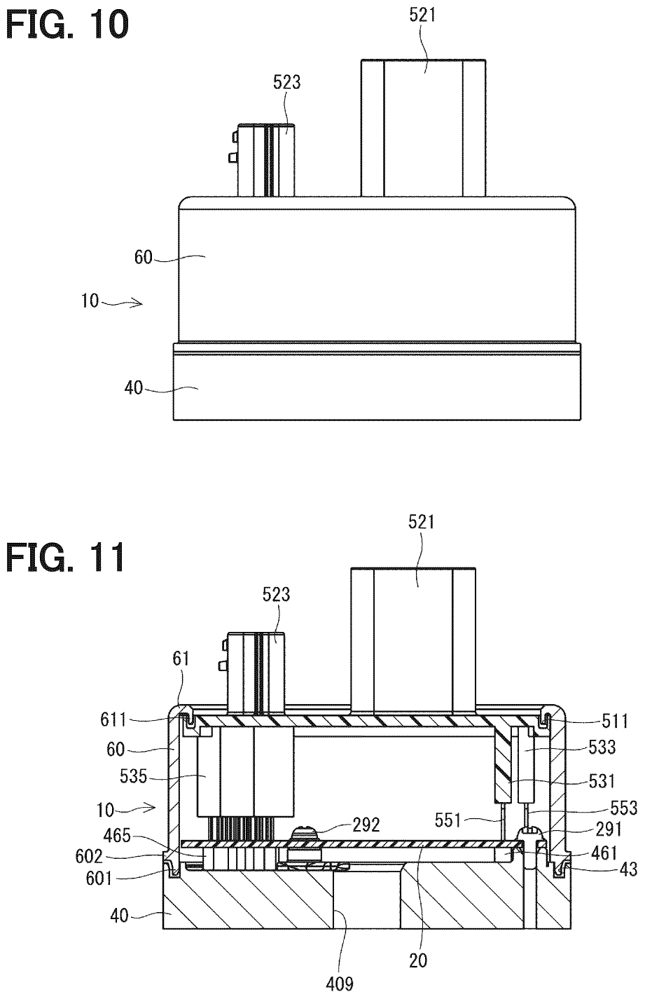

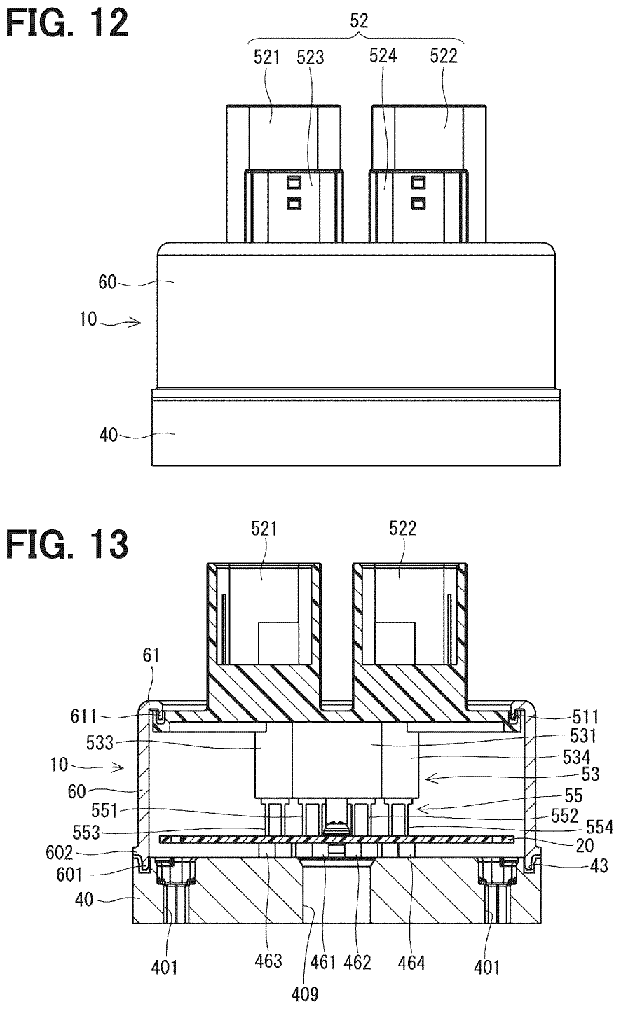

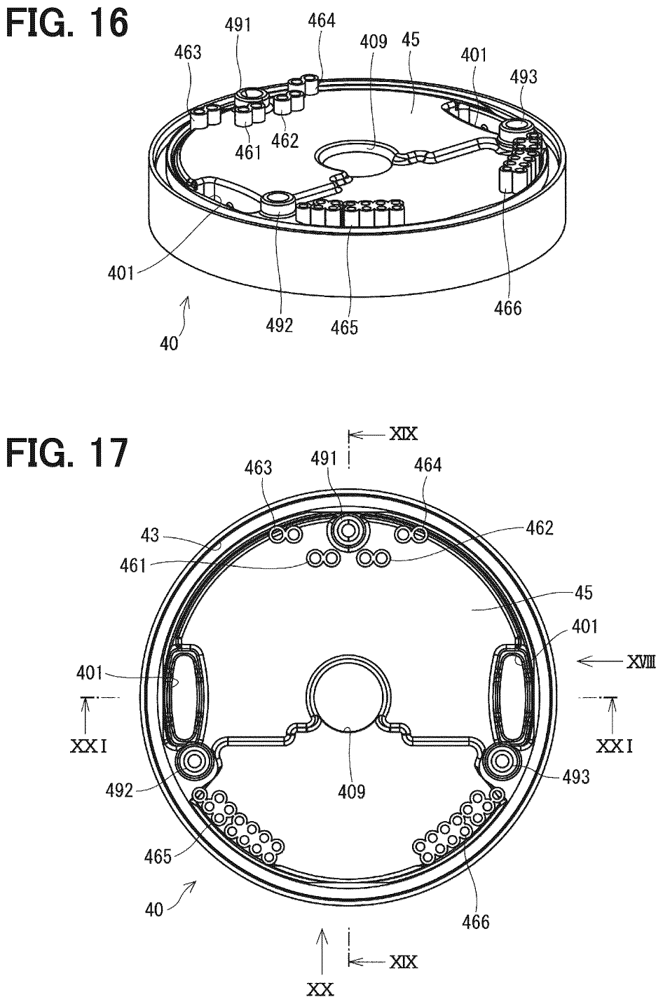

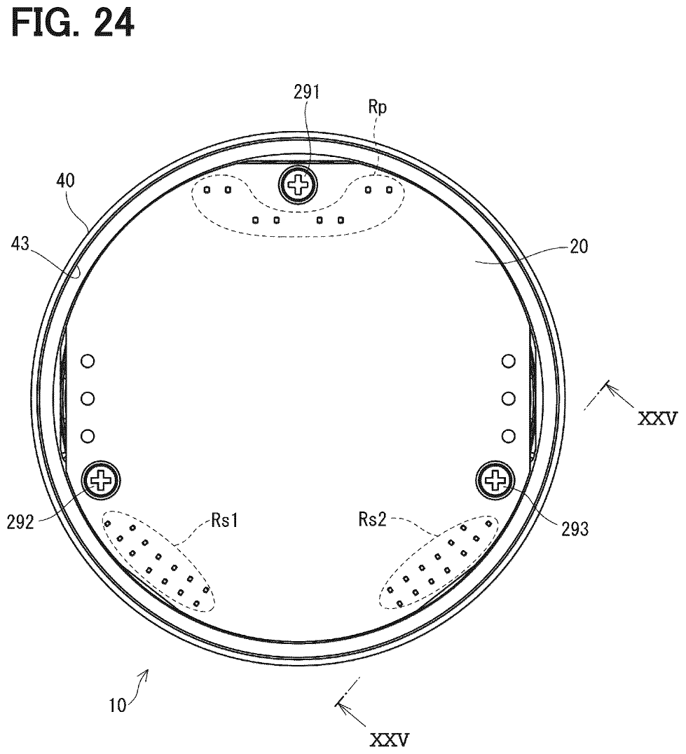

FIGS. 1 to 30 show the first embodiment. A drive device 1 includes: an electric motor 80; and an electronic control unit (ECU) 10, which serves as a control unit. The drive device 1 is applied to an electric power steering apparatus 8, which is a steering apparatus configured to assist a steering operation of a vehicle. FIG. 1 illustrates an overall structure of a steering system 90, which includes the electric power steering apparatus 8. The steering system 90 includes: a steering wheel 91, which serves as a steering member; a steering shaft 92; a pinion gear 96; a rack shaft 97; a plurality of wheels 98; and the electric power steering apparatus 8.

The steering wheel 91 is connected to the steering shaft 92. A torque sensor 93, which is configured to detect steering torque, is installed on the steering shaft 92. The pinion gear 96 is installed to a distal end portion of the steering shaft 92. The pinion gear 96 is meshed with the rack shaft 97. A pair of wheels 98 are coupled to two ends of the rack shaft 97 via tie rods or the like.

When a driver of the vehicle rotates the steering wheel 91, the steering shaft 92 connected to the steering wheel 91 is rotated. The rotational motion of the steering shaft 92 is converted into linear motion of the rack shaft 97 by the pinion gear 96. The pair of wheels 98 are steered at an angle corresponding to the amount of displacement of the rack shaft 97.

The electric power steering apparatus 8 includes: the drive device 1; and a speed reducing gear mechanism 89, which serves as a drive force transmission device configured to reduce the rotational speed of the electric motor 80 and transmit the rotation of the reduced rotational speed to the rack shaft 97. The electric power steering apparatus 8 of the present embodiment is a so-called “rack assist type,” but may alternatively be a so-called “column assist type” in which the rotation of the electric motor 80 is transmitted to the steering shaft 92.

The electric motor 80 is a three-phase brushless motor. The electric motor 80 outputs a part or all of the torque required for the steering. The electric motor 80 is driven by electric power supplied from a vehicle electric power source 5 to rotate the speed reducing gear mechanism 89 in a forward or reverse direction.

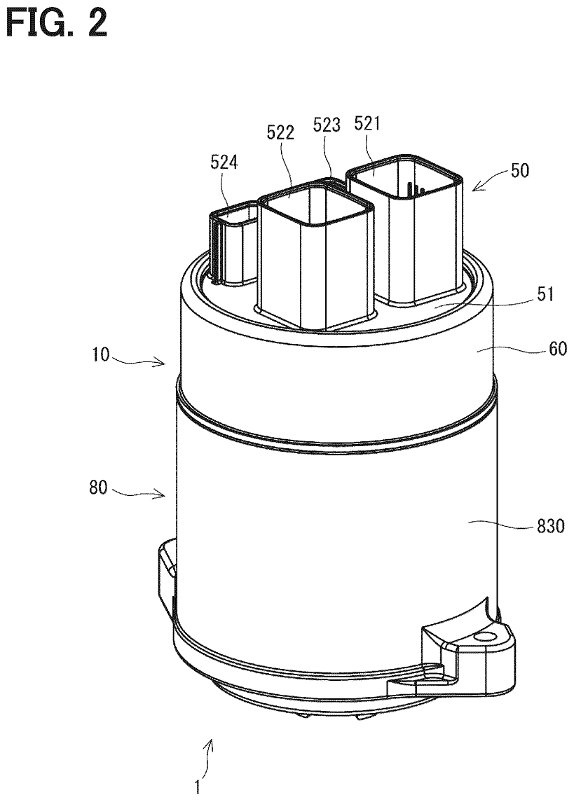

As shown in FIGS. 2 to 6, the drive device 1 is of a so-called “integrated mechanical and electrical type,” in which the ECU 10 is integrally provided on one side of the electric motor 80 in an axial direction. The ECU 10 is placed on the side opposite to an output shaft 870 of the electric motor 80 such that the ECU 10 is coaxially arranged with respect to an axis Ax of the shaft 870. In this context, the term “coaxial” is intended to encompass tolerances including deviations arising from assembly or design-related errors. Hereinafter, the axial direction of the electric motor 80 is regarded as the axial direction of the drive device 1 and is hereinafter simply referred to as the “axial direction.” The same applies to a radial direction and a circumferential direction.

The electric motor 80 includes a motor case 830, a stator 860, a rotor 865 and motor windings 880. The motor case 830 is shaped substantially in a bottomed tubular form and has a bottom portion 831 and a tubular portion 832. An opening of the motor case 830 faces the ECU 10. A bearing 871 is installed to the bottom portion 831. The stator 860 is fixed to the tubular portion 832. A frame member 40 is securely press fitted into the opening of the motor case 830.

The stator 860 is fixed to the motor case 830, and the motor windings 880 are wound around the stator 860. The motor windings 880 include two sets of three-phase windings. Hereinafter, each structural unit, which relates to energization control of a corresponding one of the two sets of three-phase windings, will be referred to as a “system.” The rotor 23 is placed on a radially inner side of the stator 860 and is configured to rotate relative to the stator 860.

The shaft 870 is fitted into the rotor 865 and is rotated integrally with the rotor 865. The shaft 870 is rotatably supported by the motor case 830 and the frame member 40 via bearings 871, 872. The ECU 10 controls energization of the motor windings 880 to generate a rotating magnetic field at the stator 860. The rotor 865 is rotated about the shaft 870 by the rotating magnetic field generated from the stator 860.

An end portion of the shaft 870 on the ECU 10 side is inserted through a shaft hole 409 formed in the frame member 40 and is exposed on the ECU 10 side. A magnet 875 is installed to the end portion of the shaft 870, which faces the ECU 10. Lead wire insertion through-holes 401 are formed in the frame member 40, and lead wires 881, each of which is connected to the corresponding motor winding 880 of the corresponding phase, are drawn out to the ECU 10 side through the lead wire insertion through-holes 401.

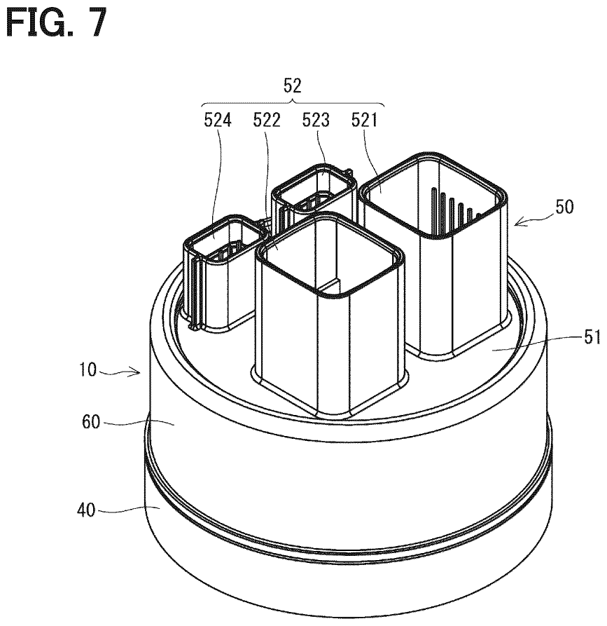

As shown in FIGS. 7 to 13, the ECU 10 includes a circuit board 20, a connector unit 50 and a cover 60. The circuit board 20 is fixed to the frame member 40 by a plurality (three in this embodiment) of fastener members 291-293, such as screws. Electronic components are installed on the circuit board 20. These electronic components include, for example, switching elements forming an inverter for driving control of the electric motor 80, a microcontroller, an Application-Specific Integrated Circuit (ASIC), and capacitors.

The switching elements and a rotational angle sensor are installed on a surface of the circuit board 20, which faces the frame member 40. The switching elements are provided such that the switching elements can release heat to a heat sink 45. The rotational angle sensor is placed at a location where the rotational angle sensor is opposed to the magnet 875. The rotational angle sensor detects the rotation of the electric motor 80 by detecting a rotating magnetic field of the magnet 875. Relatively large components, such as aluminum electrolytic capacitors, are installed on a surface of the circuit board 20, which is opposite to the frame member 40.

As shown in FIGS. 15 to 21, the frame member 40 is made of a metal material, such as an aluminum alloy, and is installed so as to close the opening of the motor case 830. The frame member 40 is shaped in a circular form when viewed in the axial direction, and a seal groove 43 is formed along an outer peripheral edge portion at a surface of the frame member 40 opposite to the electric motor 80. Furthermore, the heat sink 45, a plurality of load-bearing portions 461-466 and a plurality of circuit-board fixing portions 491-493 are provided on the surface of the frame member 40 opposite to the electric motor 80. Details of the load-bearing portions 461-466 will be described later.

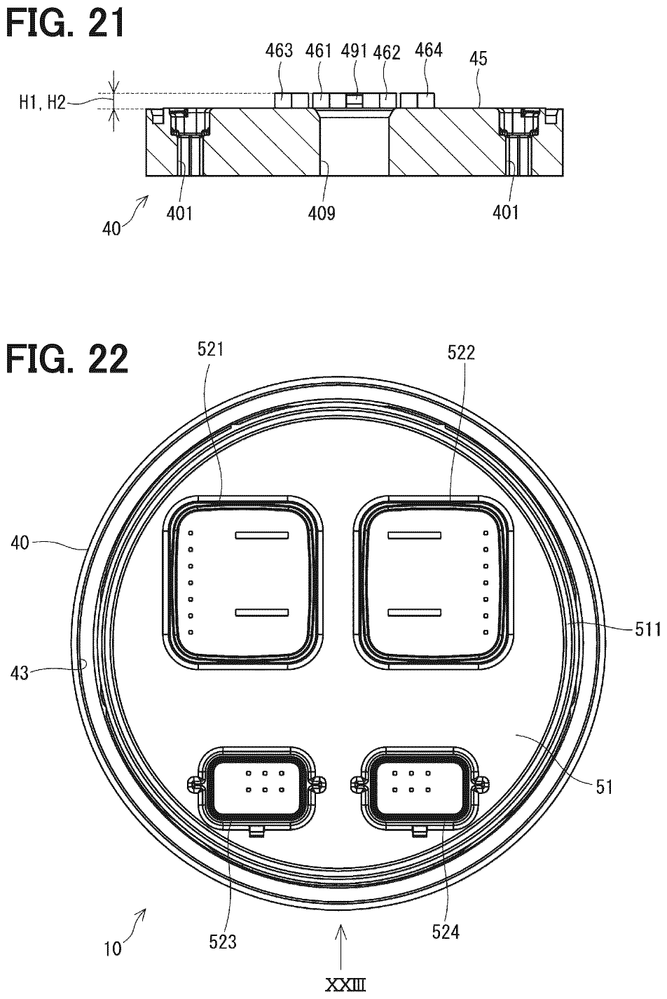

As shown in FIGS. 22 to 25, the connector unit 50 includes a base portion 51, a connector portion 52, a plurality of terminal holding portions 53 and a plurality of connector terminals 55. FIGS. 22 to 25 illustrate a state in which the cover 60 of the ECU 10 is removed. The base portion 51, the connector portion 52 and the terminal holding portions 53 are integrally formed in one-piece from a resin material.

The base portion 51 is shaped generally in a circular plate form. A seal groove 511 is formed along an outer peripheral edge portion at a surface of the base portion 51 opposite to the electric motor 80, on a radially outer side of the connector portion 52. The connector portion 52 is provided so as to project from the base portion 51 in a direction opposite to the electric motor 80. The connector portion 52 is formed such that openings of the connector portion 52 face outward in the axial direction, and the connector portion 52 is configured to allow insertion and removal of harnesses (not shown) relative to the connector portion 52.

The connector portion 52 includes: two vehicle-system connectors 521, 522; and two signal-system connectors 523, 524 connected to the torque sensor 93. One of the vehicle-system connectors 521, 522 and one of the signal-system connectors 523, 524 are provided for each system. In the present embodiment, a shape of the opening of each vehicle-system connector 521, 522 is different from a shape of the opening of each signal-system connector 523, 524.

The vehicle-system connectors 521, 522 are connected to the vehicle electric power source 5 and a vehicle communication network 6 (see FIG. 1). That is, each of the vehicle-system connectors 521, 522 of the present embodiment is a hybrid connector in which a power-system connector connected to the electric power source and the ground, and the communication-system connector connected to the vehicle communication network 6 are integrated. The vehicle communication network 6 of the present embodiment is a Controller Area Network (CAN), but may be another type of communication network. In FIG. 1, the vehicle communication network 6 is labeled as “CAN.”

The terminal holding portions 53 project toward the electric motor 80 from the base portion 51 in an outer peripheral region which is on a radially outer side of the connector portion 52, and corresponding connector terminals 55 are molded inside each of the terminal holding portions 53. Each of the connector terminals 55 projects from a distal end of the corresponding one of the terminal holding portions 53. Here, the outer peripheral region is defined as a region outside a projected region onto which the connector portion 52 is projected in the axial direction on the circuit board 20.

The terminal holding portions 53 include a power supply terminal holding portion 531, ground terminal holding portions 533, 534 and signal terminal holding portions 535, 536. There is provided the single power supply terminal holding portion 531 which is common to the two systems. The ground terminal holding portion 533 is provided for one of the two systems, and the ground terminal holding portion 534 is provided for the other. Similarly, the signal terminal holding portion 535 is provided for one of the two systems, and the signal terminal holding portion 536 is provided for the other one.

The connector terminals 55 include power supply terminals 551, 552, ground terminals 553, 554 and signal terminals 555, 556. The power supply terminals 551, 552 are connected to the vehicle electric power source 5, and the ground terminals 553, 554 are connected to the vehicle ground. The signal terminals 555, 556 include terminals connected to the vehicle communication network 6 and terminals connected to the torque sensor 93.

One end portion of each power supply terminal 551, 552 is provided in the corresponding one of the vehicle-system connectors 521, 522, and a middle portion of each power supply terminal 551, 552 is embedded in the base portion 51 and the power supply terminal holding portion 531, and two distal end portions of each power supply terminal 551, 552 project from the power supply terminal holding portion 531.

One end portion of the ground terminal 553 is provided in the vehicle-system connector 521, and a middle portion of the ground terminal 553 is embedded in the base portion 51 and the ground terminal holding portion 533, and a distal end portion of the ground terminal 553 projects from the ground terminal holding portion 533. One end portion of the ground terminal 554 is provided in the vehicle-system connector 522, and a middle portion of the ground terminal 554 is embedded in the base portion 51 and the ground terminal holding portion 534, and a distal end portion of the ground terminal 554 projects from the ground terminal holding portion 534.

One end portion of each signal terminal 555 is provided in the vehicle-system connector 521 or the signal-system connector 523, and a middle portion of the signal terminal 555 is embedded in the base portion 51 and the signal terminal holding portion 535, and a distal end portion of the signal terminal 555 projects from the signal terminal holding portion 535. One end portion of each signal terminal 556 is provided in the vehicle-system connector 522 or the signal-system connector 524, and a middle portion of the signal terminal 556 is embedded in the base portion 51 and the signal terminal holding portion 536, and a distal end portion of the signal terminal 556 projects from the signal terminal holding portion 536.

The power supply terminal holding portion 531 and the ground terminal holding portions 533, 534 are provided in a relatively consolidated manner in the outer peripheral region at a location adjacent to the vehicle-system connectors 521, 522. The ground terminal holding portions 533, 534 are provided on two opposite sides, respectively, of the power supply terminal holding portion 531.

The power supply terminals 551, 552 are connected to the circuit board 20 in a region that is on a radially inner side of the fastener member 291. The ground terminals 553, 554 are provided on two opposite sides, respectively, of the fastener member 291. That is, the power supply terminals 551, 552 and the ground terminals 553, 554 are connected to the circuit board 20 so as to surround the fastener member 291. The power supply terminals 551, 552 and the ground terminals 553, 554 are arranged side by side when viewed from the radially outer side.

The signal terminal holding portions 535, 536 are provided apart from each other in the outer peripheral region at a location adjacent to the signal-system connectors 523, 524. The signal terminals 555, 556 include torque signal terminals connected to the torque sensor 93, and communication terminals connected to the vehicle communication network 6. The signal terminals 555 are arranged adjacent to the fastener member 292 in the circumferential direction, and the signal terminals 556 are arranged adjacent to the fastener member 293 in the circumferential direction. The signal terminals 555 are arranged in two radial rows such that seven of the signal terminals 555 are arranged in a radially inner one of the two radial rows, and six of the signal terminals 555 are arranged in a radially outer one of the two rows. Similarly, the signal terminals 556 are arranged in two radial rows such that seven of the signal terminals 556 are arranged in a radially inner one of the two radial rows, and six of the signal terminals 556 are arranged in a radially outer one of the two rows. However, the number of these terminals and the arrangement of these terminals can be arbitrarily designed according to the number of signals or the like.

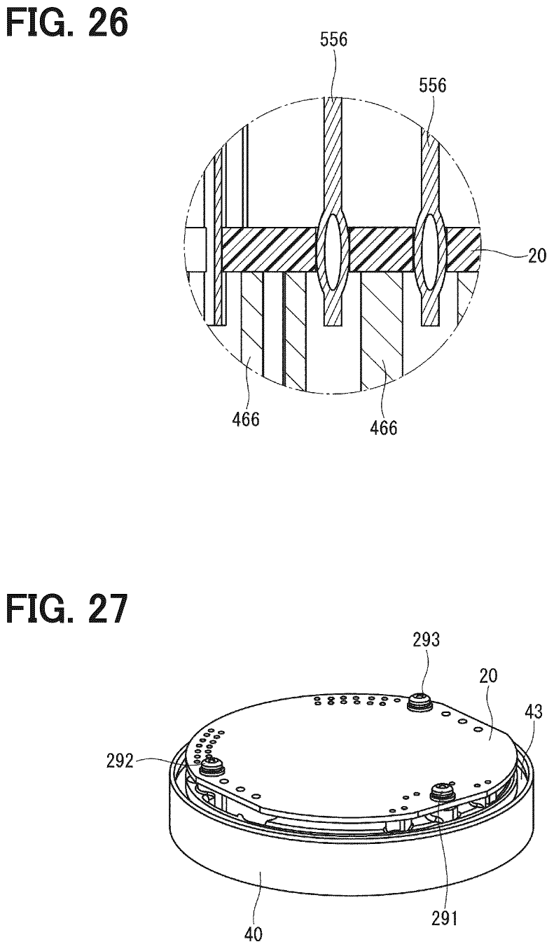

The distal end portion of each of the terminals 551-556 is shaped in a ring form and is resiliently deformable, and this distal end portion of each of the terminals 551-556 is mechanically and electrically connected to the circuit board 20 by press-fit connection (see FIG. 26). Although the signal terminals 556 are illustrated in FIG. 26 as an example, the distal end portions of the other terminals 551-555 are also shaped in the same form.

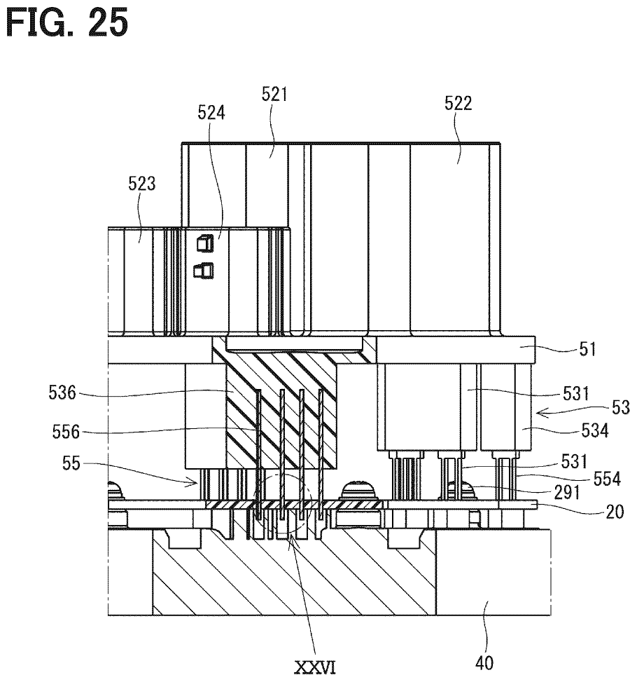

A base portion of each power supply terminal 551, 552, which is exposed from the power supply terminal holding portion 531, is shaped in a wide flat-plate form, and the distal end side of each power supply terminal 551, 552 is branched into a plurality of portions (two portions in the present embodiment) (see FIG. 25, etc.). Similarly, the base portions of the ground terminals 553, 554, each of which is exposed from the corresponding ground terminal holding portion 533, 534, are respectively formed in a wide flat-plate shape, and a distal end portion of each of the ground terminals 553, 554 is branched into a plurality of portions (two portions in the present embodiment). In the case of press-fit connection, each of the terminals needs to be formed relatively thin in order to resiliently deform the connecting portion thereof. On the other hand, if each of the terminals is too thin, it becomes difficult to conduct a large electric current. Therefore, by branching the distal end portions of the terminals 551-554 into the plurality of portions, both press-fit connection and the conduction of the large electric current are made possible.

A region, in which the power supply terminals 551, 552 and the ground terminals 553, 554 are connected, is defined as a power terminal region Rp. Also, a region, in which the signal terminals 555 are connected, is defined as a signal terminal region Rs1, and a region, in which the signal terminals 556 are connected, is defined as a signal terminal region Rs2. These regions Rp, Rs1, Rs2 are spread apart from one another in the outer peripheral region. In the present embodiment, by spreading the terminal regions into these three locations, the connector unit 50 is held on the circuit board 20 solely by the press-fit connections of the terminals 551-556, without using any fastener members such as screws.

In the present embodiment, the relatively large components, such as the aluminum electrolytic capacitors, are mounted on the surface of the circuit board 20 opposite to the electric motor 80, and a separation space is provided between the circuit board 20 and the base portion 51 in accordance with the heights of the mounted electronic components. Accordingly, the axial length of the terminal holding portions 531-536 is set to a dimension that allows the terminals 551-556 to support the load of the connector unit 50 without buckling. In the present embodiment, the axial length of the terminal holding portions 531-536 is equal to or larger than one half of the distance between the circuit board 20 and the base portion 51.

As shown in FIGS. 17 to 21 and 29, load-bearing portions 461-466, which bear press-fit loads from the terminals 551-556, are formed to project from the surface of a frame portion 41 of the frame member 40, which is opposite to the electric motor 80, and the load-bearing portions 461-466 are configured to come into contact with the circuit board 20 at the top surfaces of the load-bearing portions 461-466. Each of the load-bearing portions 461-466 is shaped in a tubular form into which the distal end portion of the corresponding one of the terminals is inserted.

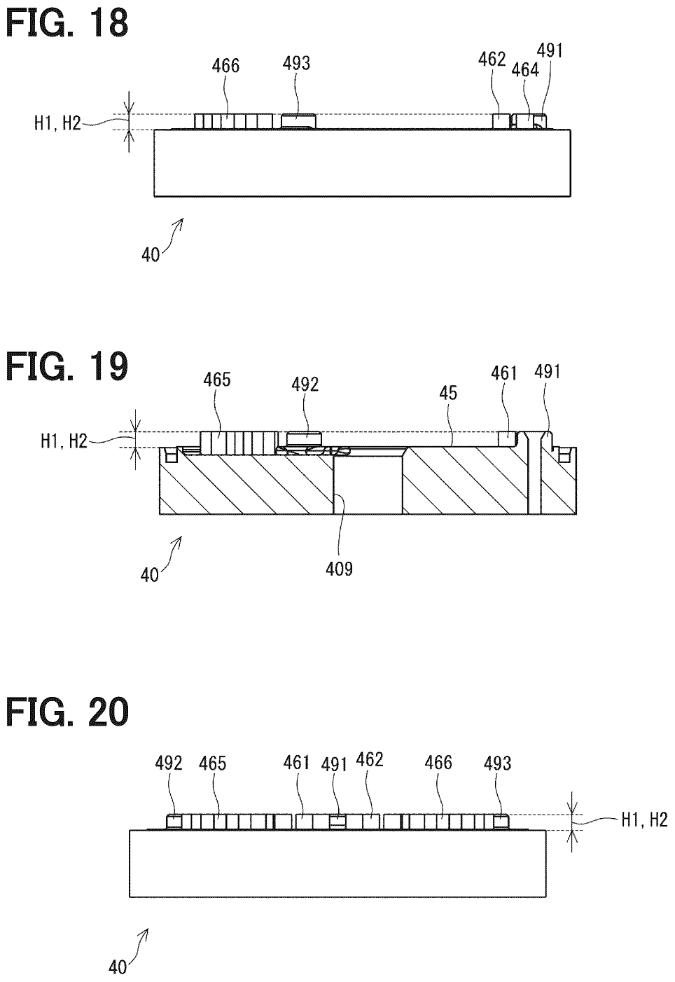

A height H1 of each of the load-bearing portions 461-466 is larger than a height of the heat sink 45 and is equal to a height H2 of each of the circuit-board fixing portions 491-493 (see FIGS. 18 to 21). Here, the height refers to an axial length measured from a reference surface, in which the heat sink 45 or the like is not formed, on the surface of the frame member 40 opposite to the electric motor 80. Furthermore, the expression “the height is equal” is intended to allow a tolerance to the extent that the load-bearing portions 461-466 can adequately bear the press-fit load. The same applies to the embodiments described later.

The load-bearing portions 461-464 are in contact with the circuit board 20 in the terminal region Rp. The load-bearing portions 461, which are formed by joining two tubular portions corresponding to the branched distal end portions of the power supply terminal 551, are provided at the connection between the power supply terminal 551 and the circuit board 20, and the load-bearing portions 462, which are formed by joining two tubular portions corresponding to the branched distal end portions of the power supply terminal 552, are provided at the connection between the power supply terminal 552 and the circuit board 20. The load-bearing portions 463, which are formed by joining two tubular portions corresponding to the branched distal end portions of the ground terminal 553, are provided at the connection between the ground terminal 553 and the circuit board 20, and the load-bearing portions 464, which are formed by joining two tubular portions corresponding to the branched distal end portions of the ground terminal 553, are provided at the connection between the ground terminal 553 and the circuit board 20.

The load-bearing portions 465 contact the circuit board 20 in the terminal region Rs1, and the load-bearing portions 466 contact the circuit board 20 in the terminal region Rs2. The load-bearing portions 465 are formed by joining tubular portions, which correspond to the signal terminals 555, respectively. The load-bearing portions 466 are formed by joining tubular portions, which correspond to the signal terminals 556, respectively.

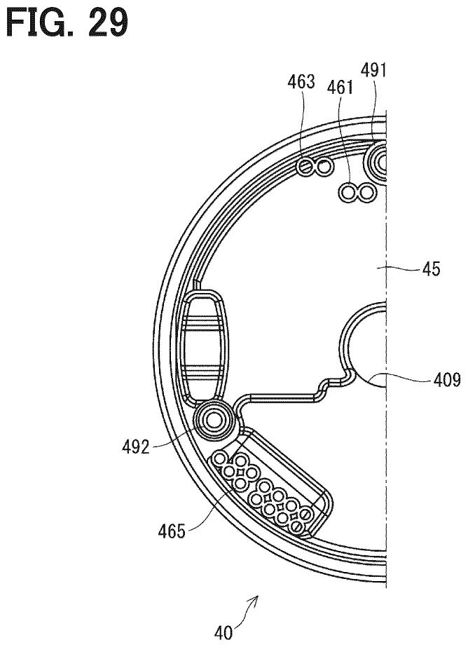

FIG. 30 indicates a relationship between the load-bearing portion 461-465 and the wiring pattern of the circuit board 20. FIG. 30 illustrates an example in which the circuit board 20 is a six-layer circuit board, and the power supply terminal 551 and the load-bearing portion 461 are shown. The load-bearing portion 461 is provided at a location that is spaced apart from the wiring pattern 21 of the through-hole, through which the terminal 551 is inserted, by an insulation gap G (e.g., 0.5 mm) or more. Further, with respect to the circuit board 20, it is assumed that an upper end of the circuit board 20 in the drawing corresponds to a first layer, and a lower end of the circuit board 20 in the drawing corresponds to an Nth layer (N=6 in the case of the six-layer circuit board). In such a case, no wiring pattern is provided in the Nth layer at a location where the load-bearing portion 461 is formed, and the circuit board 20 is in contact with the load-bearing portion 461 via a resist layer (serving as an electrical insulation layer). Further, the wiring pattern connected to the terminal 551 is formed in the first layer to the (N−1)th layer. This makes it possible to ensure the electrical insulation between each terminal 551 and the corresponding load-bearing portion 461.

It should be noted that at each of corresponding contact locations where the load-bearing portions 463, 464 corresponding to the ground terminals 553, 554 contact the circuit board 20, a ground pattern may be formed in the Nth layer, and the ground pattern may be brought into contact with the load-bearing portions 463, 464.

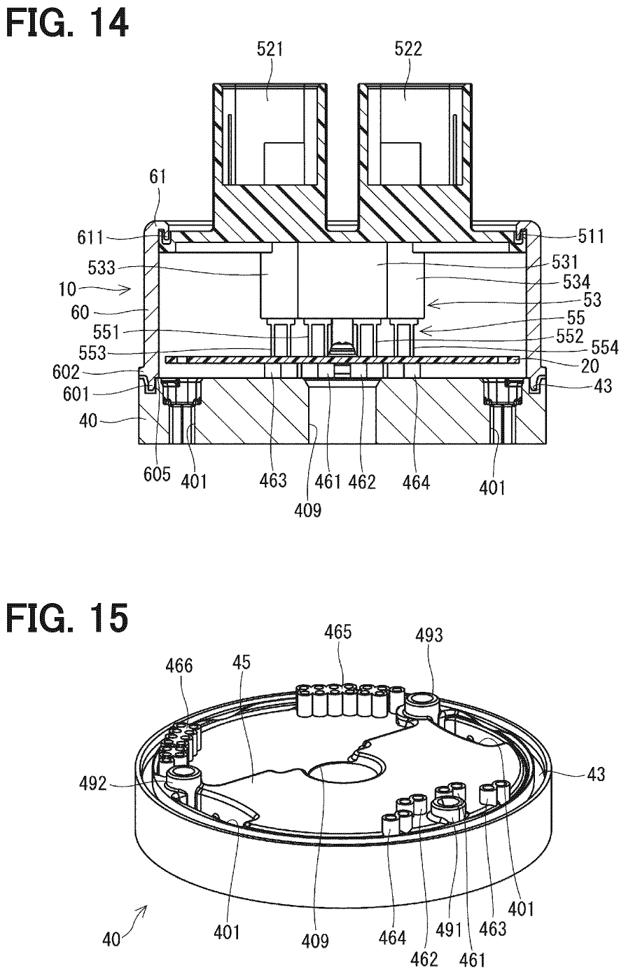

As shown in FIGS. 2 to 13, the cover 60 is shaped substantially in a tubular form and is made of, for example, aluminum. An inserting portion 601, which is fitted into a seal groove 43 of the frame portion 41, is formed at one end portion of the cover 60 which faces in the axial direction. A flange 602 is formed on the cover 60 at a location which is opposed to a radially outer portion of the seal groove 43. Further, as shown in FIG. 14, a seat portion 605, which is configured to contact the frame member 40 at a radially inner side of the seal groove 43, may be formed on the cover 60.

Referring back to FIG. 13, a ring portion 61, which is bent radially inward, is formed at the other end portion of the cover 60 which faces in the axial direction. An inserting portion 611 is formed at a distal end of the ring portion 61. The inserting portion 611 is configured to be fitted into the seal groove 511 of the base portion 51 of the connector unit 50. By installing the cover 60 in a state in which an adhesive is applied to the seal grooves 43, 511, the cover 60 is fixed to the frame member 40 and the connector unit 50 with the adhesive.

For example, as discussed at the beginning of the “DETAILED DESCRIPTION” of the present application, in the previously proposed technique in which the connectors and the cover are integrally formed, the connectors and the circuit board are assembled in the blind state, in which the connection between the connectors and the circuit board cannot be seen. This makes it difficult to inspect whether the terminals are correctly inserted into the terminal holes of the circuit board. Furthermore, in the case where the adhesive is used to connect the cover, which is formed integrally in one-piece with the connector, to the motor frame, when there is a difference in a coefficient of linear expansion between the connectors and the adhesive, the connections between the connector terminals and the circuit board may be affected by expansion and/or contraction induced by temperature changes. Therefore, there are risks such as disengagement of the terminals or wear, making it difficult to ensure the reliability of the connections.

In view of the above issues, in the present embodiment, the connector terminals 55 are integrally formed in the connector unit 50, which is an assembly and is formed separately from the cover 60 by resin molding, and the connector unit 50 is assembled to the circuit board 20 fixed to the frame member 40.

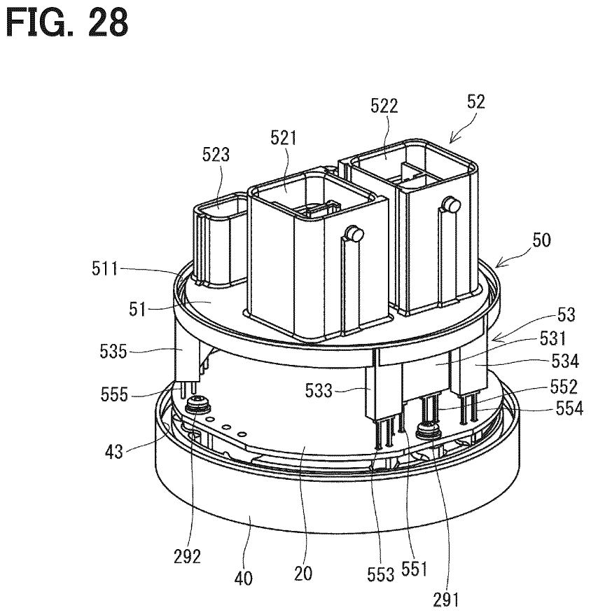

Specifically, as shown in FIG. 27, the circuit board 20 is assembled to the frame member 40. Subsequently, as shown in FIG. 28, the connector unit 50 is assembled by press-fitting and connecting the terminals 551-556 into the circuit board 20. Then, starting from the state, in which the connector unit 50 is assembled to the circuit board 20, the cover 60 is placed over them, and the cover 60 is assembled to the frame member 40 and the connector unit 50 (see, for example, FIG. 7).

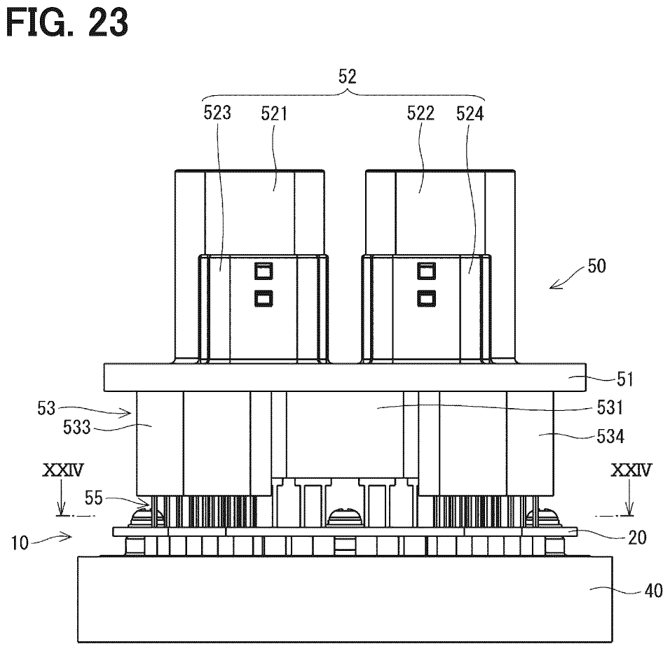

In the present embodiment, since the connector unit 50 and the cover 60 are formed separately from each other, the connector unit 50 and the circuit board 20 can be connected with each other in a visually observable state, as shown in, for example, FIG. 23. Furthermore, by forming the connector unit 50 and the cover 60 as the separate components, the connections between the terminals 551-556 and the circuit board 20 are not directly affected by the thermal deformation of the adhesive, which has a larger coefficient of linear expansion than the connector resin, thereby suppressing a decrease in reliability of the connections.

As a comparative example, in a case where the circuit board and the connectors are assembled together offline and then assembled to the electric motor, it is necessary to reserve space for the electrical connection between the electric motor and the circuit board, as well as for fixing the circuit board. This leads to a reduction in an available surface area for placing the connectors. In contrast, in the present embodiment, by assembling the circuit board 20 to the frame member 40, the connector unit 50 can be connected to the circuit board 20 after the lead wires 881 are connected to the circuit board 20. This makes it possible to assemble the circuit board 20 to the frame member 40 and to connect the electric motor 80 to the circuit board 20 in a state where the connectors are not yet present, thereby allowing for a larger space to be secured for placing the connectors. Furthermore, by providing the load-bearing portions 461-466, it is unnecessary to use a jig or the like to suppress deformation of the circuit board 20 caused by terminal insertion load.

As described above, the drive device 1 includes the electric motor 80, the frame member 40, the circuit board 20, the connector unit 50 and the cover 60. The frame member 40 is located on the one side of the electric motor 80 in the axial direction. The circuit board 20 is fixed to the frame member 40 on the side opposite to the electric motor 80.

The connector unit 50 includes: the base portion 51; the connector portion 52, which is located on the one side of the base portion 51 opposite to the electric motor 80; and the plurality of terminal holding portions 53, which are formed integrally with the base portion 51 and the connector portion 52 in one-piece and are located on the other side of the base portion 51 where the electric motor 80 is placed. The connector unit 50 includes the plurality of connector terminals 55, which project from the plurality of terminal holding portions 53. The plurality of connector terminals 55 resiliently contact and are thereby mechanically and electrically connected to the circuit board 20. The cover 60 is formed separately from the connector unit 50 and receives the circuit board 20 and the plurality of connector terminals 55 in the state in which the connector portion 52 is exposed outside the cover 60.

The plurality of load-bearing portions 461-466 are formed on the frame member 40 in the terminal regions where the plurality of connector terminals 55 are connected to the circuit board 20, and the plurality of load-bearing portions 461-466 project toward and contact the circuit board 20. Specifically, in the present embodiment, a distal end portion of each of the plurality of connector terminals 55, which is inserted through the circuit board 20, is defined as a terminal distal end portion, and each of the plurality of load-bearing portions 461-466 is shaped in a ring form and surrounds an outer periphery of the terminal distal end portion of the corresponding one of the plurality of connector terminals 55.

In the present embodiment, since the connector unit 50 and the cover 60 are formed separately, the connector terminals 55 can be connected to the circuit board 20 in the state, in which the connections between the connector terminals 55 and the circuit board 20 are not yet covered by the cover 60. Therefore, it is possible to inspect whether the connector terminals 55 have been correctly inserted into the circuit board 20. Furthermore, since the load-bearing portions 461-466, each of which is configured to bear the load during the press-fit connection, are formed, the press-fit load can be appropriately supported. Therefore, the connector can be properly assembled.

The plurality of circuit-board fixing portions 491-493, to which the circuit board 20 is fixed by the plurality of fastener members 291-293, are formed on the frame member 40. The height H1 of each of the load-bearing portions 461-465 is equal to the height H2 of each of the circuit-board fixing portions 491-493. Accordingly, the press-fit load can be appropriately borne by the load-bearing portions 461-466.

Each of the plurality of load-bearing portions 461-466 is spaced away from the wiring pattern formed in the corresponding one of the plurality of through-holes of the circuit board 20, through which the plurality of connector terminals 55 are respectively inserted, and each of the plurality of load-bearing portions 461-466 contacts the circuit board 20 via the electrical insulation layer. This makes it possible to ensure the electrical insulation between each connector terminal 55 and the circuit board 20.

The cover 60 has: the inserting portion 601, which is located on the radially outer side of the circuit board 20 and is fixed to the frame member 40 on the one side of the frame member 40 opposite to the electric motor 80; and the inserting portion 611, which is located on the radially outer side of the connector portion 52 and is fixed to the base portion 51 on the one side of the base portion 51 opposite to the electric motor 80. This makes it possible to properly assemble the cover 60 by placing the cover 60 from the side opposite to the electric motor 80 in the state, in which the connector unit 50 is already assembled to the circuit board 20.

### Second Embodiment

FIGS. 31 to 34 show the second embodiment. Since the second and third embodiments mainly differ from the above-described embodiment in the structure of the load-bearing portions, the following description will focus on this point. FIG. 31 corresponds to FIG. 29 of the first embodiment. In FIG. 31, since the right-side portion with respect to the break line is substantially symmetrical to the left-side portion, descriptions and explanations are partially omitted as appropriate.

As shown in FIG. 31, the load-bearing portions 71, 72 are formed to project from the surface of the frame member 40 on the side opposite to the electric motor 80. The height of each load-bearing portion 71, 72 is the same as the height of each circuit-board fixing portion 491-493, as in the above-described embodiment. Each of the load-bearing portions 71, 72 is spaced from the corresponding terminal 551-556 by a distance (e.g., 0.5 mm) sufficient to ensure electrical insulation.

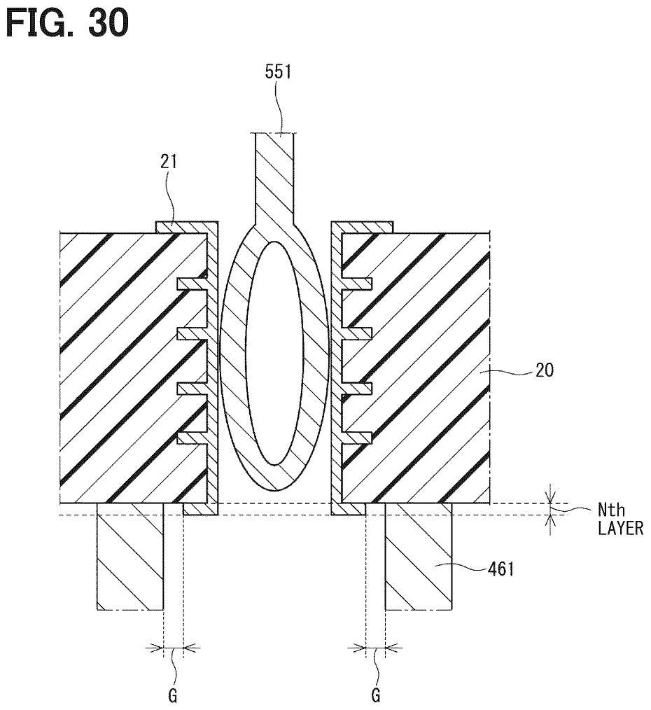

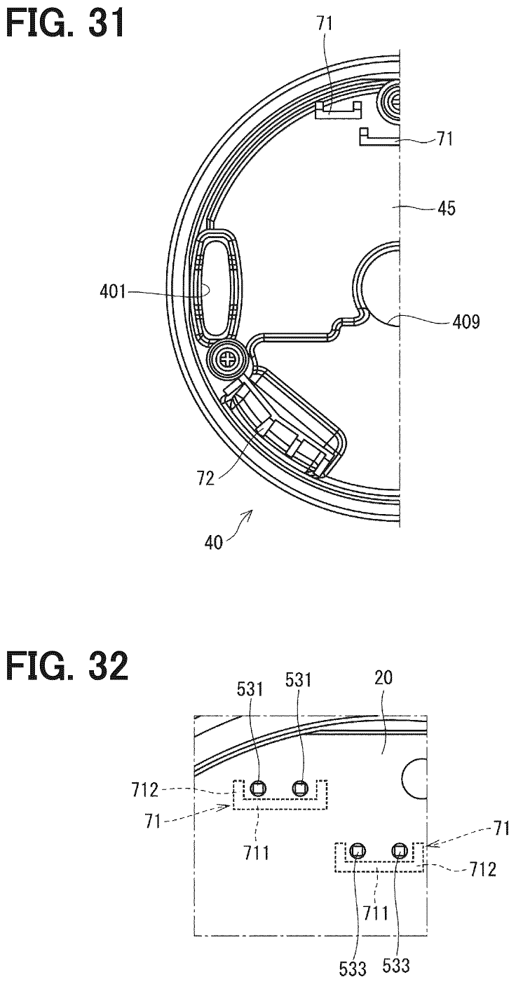

As shown in FIG. 32, the load-bearing portion 71 is provided to the distal end portions of the power supply terminal 551. Specifically, the load-bearing portion 71 has: an inner wall 711, which is formed on a radially inner side of the two distal end portions of the power supply terminal 551; and two side walls 712, which extend radially outward from two opposite ends of the inner wall 711. Thereby, the load-bearing portion 71 has a shape that opens radially outward as a whole. Similarly, one load-bearing portion 71 is provided for two distal end portions of the power supply terminal 552 and also for two distal end portions of each of the ground terminals 553, 554.

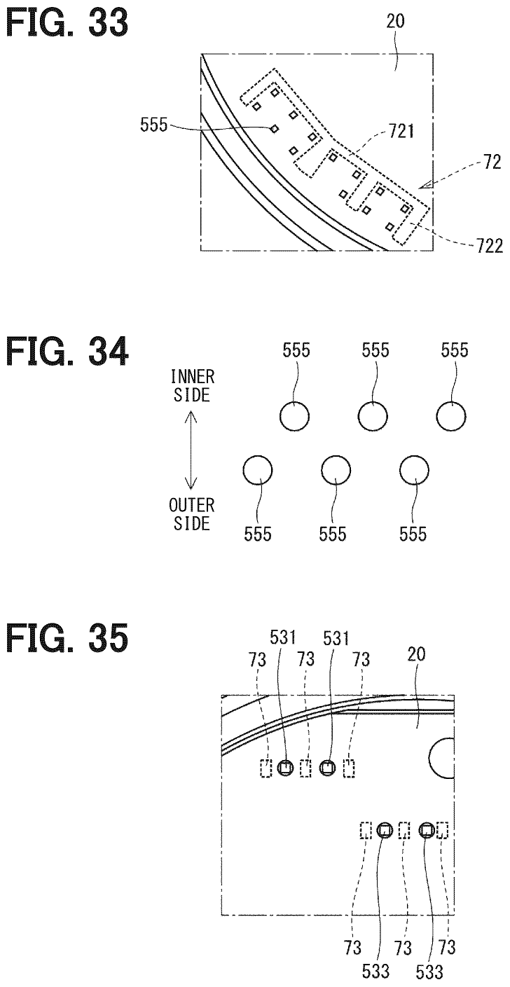

As shown in FIG. 33, one load-bearing portion 72 is provided for the group of the signal terminals 555. Specifically, the load-bearing portion 72 has: an inner wall portion 721, which is formed on a radially inner side of the signal terminals 555; and two side wall portions 722, which extend radially outward from two opposite ends of the inner wall portion 711. Thereby, the load-bearing portion 72 has a shape that opens radially outward as a whole. The side wall portions 722 are provided at both ends of the inner wall portion 721, as well as between the terminals.

In the example shown in FIG. 33, the number of the side wall portions 722, which are provided between the terminals, is two, and thereby a total of three openings are formed. However, the positions, the number, and the shapes of the side wall portions 722 may be appropriately set depending on the load or other conditions. Furthermore, the load-bearing portion 72 may be divided into a plurality of segments.

Each of the load-bearing portions 71, 72 is shaped in the corresponding form that surrounds the plurality of terminals and opens toward the radially outer side. This allows the connection states of the terminals 551-556 to be checked from the radially outer side after the terminals 551-556 have been connected to the circuit board 20. Furthermore, as shown in FIG. 34, in a case where the signal terminals 555 are arranged in a plurality of rows which are radially displaced from each other and each of which includes one or more (more than one in this instance) of the signal terminals 555, the one or more signal terminals 555 in a radially inner one of the plurality of rows may be circumferentially displaced relative to the one or more signal terminals 555 in a radially outer one of the plurality of rows positioned on a radially outer side of the radially inner one of the plurality of rows. This facilitates the inspection of the connection states of the terminals arranged on the inner side. It should be noted that, although there is explained the example in which the terminals 555 are arranged in two rows, the above-described circumferential displacement of the terminals 555 can be also applied to cases where the terminals are arranged in three or more rows.

In the present embodiment, the distal end portion of each of the plurality of connector terminals 55, which is inserted through the circuit board 20, is defined as the terminal distal end portion, and each of the plurality of load-bearing portions 71, 72 is at least partially opened and thereby partially surrounds a corresponding one of a plurality of terminal groups, each of which includes two or more of the terminal distal end portions of the plurality of connector terminals 55. Each of the load-bearing portions 71, 72 of the present embodiment is radially outwardly opened and thereby partially surrounds the corresponding terminal group. As a supplementary note, the term “terminal group” is not limited to multiple terminals such as the signal terminals 555, 556, but also includes, for example, the two terminal distal end portions of the power supply terminal 551 that share the common base portion.

The plurality of connector terminals 55 are arranged in the plurality of rows that are radially displaced from each other, and each of the plurality of rows includes the one or more connector terminals 55 among the plurality of connector terminals 55. The one or more connector terminals 55 in the radially inner one of the plurality of rows are circumferentially displaced relative to the one or more connector terminals 55 in the radially outer one of the plurality of rows positioned on the radially outer side of the radially inner one of the plurality of rows. This makes it possible to inspect the connection state between the circuit board 20 and the connector terminals 55 after the connector unit 50 is assembled to the circuit board 20. Furthermore, the advantages similar to those described in the above embodiment can be achieved.

### Third Embodiment

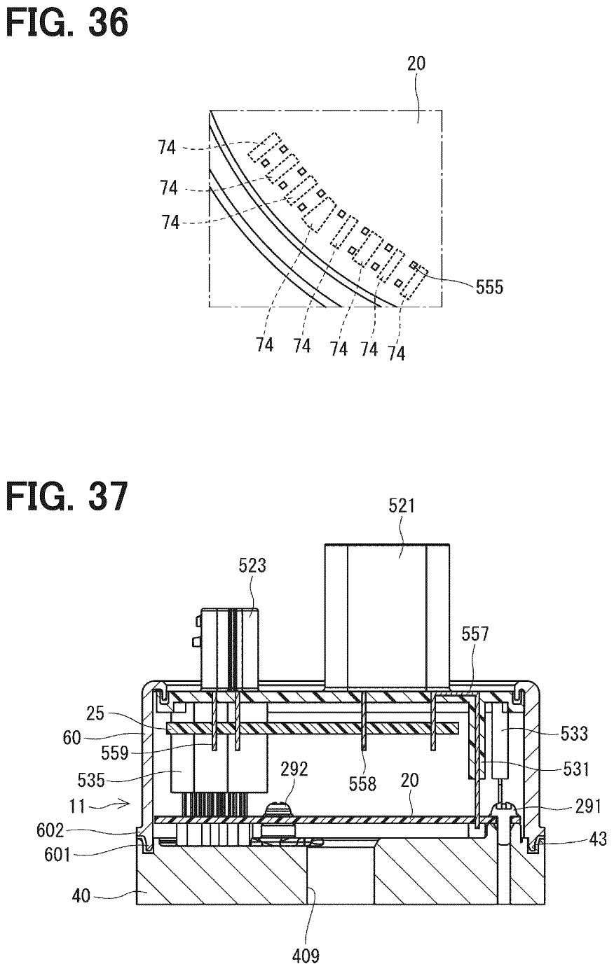

FIGS. 35 and 36 show the third embodiment. In the third embodiment, the load-bearing portions 73, 74 are formed to project from the surface of the frame member 40 on the side opposite to the electric motor 80. The height of each load-bearing portion 73, 74 is the same as the height of each circuit-board fixing portion 491-493, as in the above-described embodiments. Each of the load-bearing portions 73, 74 is spaced from the corresponding terminal 551-556 by a distance (e.g., 0.5 mm) sufficient to ensure electrical insulation.

As shown in FIG. 35, two of the load-bearing portions 73 are respectively located on two opposite sides of the two distal end portions of the power supply terminal 551, and one of the load-bearing portions 73 is located between the two distal end portions of the power supply terminal 551. Similarly, for the ground terminal 553, two of the load-bearing portions 73 are respectively located on two opposite sides of the two distal end portions of the ground terminal 553, and one of the load-bearing portions 73 is located between the two distal end portions of the ground terminal 553.

As shown in FIG. 36, corresponding two of the load-bearing portions 74 are located on two opposite sides of each adjacent two of the signal terminals 555, which are arranged adjacent to each other generally in the circumferential direction, and corresponding one of the load-bearing portions 74 is located between the adjacent two of the signal terminals 555. The load-bearing portions 74 may also be said to extend in a direction generally along the radial direction and to be arranged adjacent to the signal terminals 555.

The positions, the number, the shapes and the like of the load-bearing portions 73, 74 can be appropriately set in accordance with the load and other factors applied during the terminal insertion. For example, with respect to the load-bearing portions 73, they may be formed only on the two opposite sides of the two distal end portions of the power supply terminal 551, and may be omitted between the two distal end portions of the power supply terminal 551. Also, for example, with respect to the load-bearing portions 74, it is not necessary to provide them between all of the terminals, and some of them may be omitted, such as by providing them at every other terminal or every two terminals.

Since the load-bearing portions 73, 74 are formed so as to extend from the inner side to the outer side of the circuit board 20, the connection states of the terminals 551-556 with the circuit board 20 can be inspected from the radially outer side after the terminals 551, 556 are connected to the circuit board 20.

In the present embodiment, the load-bearing portions 73, 74 are located adjacent to the terminal distal end portions. Here, the phrase “located adjacent to” means that a gap sufficient to ensure electrical insulation is provided, and that no other member is disposed between the terminal distal end portion and the load-bearing portion. Specifically, each of the load-bearing portions 73, 74 include at least one of: the outer walls, which are located on two opposite sides of the corresponding terminal distal end portions; and the partition wall(s), which partitions between the terminals. Even with such a configuration, the same effects as those of the above-described embodiments can be achieved.

### Fourth Embodiment

FIG. 37 shows the fourth embodiment. FIG. 37 is a cross-sectional view corresponding to FIG. 11, and an ECU 11 includes, in addition to the circuit board 20, a connector circuit board 25. That is, the two circuit boards are provided in the ECU 11 of the present embodiment. The number of the circuit boards may be three or more. The connector circuit board 25 is fixed to the surface of the base portion 51 of the connector unit 50, which faces the electric motor 80, by fastener members such as screws (not shown). The connector circuit board 25 is connected to the circuit board 20 via board-to-board connection components (not shown) to enable sending and receiving various signals between the connector circuit board 25 and the circuit board 20.

Power terminals 557 include the power supply terminal and the ground terminal. one end portion of each power terminal 557 is received in the corresponding vehicle-system connector 521, 522, and the power terminal 557 is branched at the inside of the base portion 51. One of the branched distal end portions of the power terminal 557 is connected to the connector circuit board 25, and the other one of the branched distal end portions is connected to the circuit board 20. The configuration of the other end portion of the branched distal end portions, which is connected to the circuit board 20, is the same as that in the above-described embodiment. One end portion of each signal terminal 558 is received in the corresponding vehicle-system connector 521, 522 and the other end portion of the signal terminal 558 is connected to the connector circuit board 25.

One end portion of each signal terminal 559 is received in the corresponding signal-system connector 523, 524, and the other end portion of the signal terminal 559 is connected to the connector circuit board 25. In addition to the signal terminals 558, 559, the signal terminals 555, 556 described in the above embodiment are also provided. Even with such a configuration, the same effects as those of the above-described embodiments can be achieved.

In the embodiments described above, the inserting portion 601 serves as a first fixing portion, and the inserting portion 611 serves as a second fixing portion. In addition, the power terminal region Rp and the signal terminal regions Rs1, Rs2 serve as terminal regions (at least one terminal region).

### Other Embodiments

In the embodiments described above, the distal end portion of each of the terminals 551-556 is shaped in the ring form. In another embodiment, the distal end portion of the terminal may have another shape, which is other than the ring form, as long as it allows the connection of the distal end portion of the terminal through the resilient deformation thereof. In another embodiment, the shape of each of the load-bearing portions may be different from the shape described in the above embodiments, as long as the load-bearing portion is capable of bearing the press-fit load. In another embodiment, the shape of each of the load-bearing portions may differ for each terminal region.

In the embodiments described above, the terminal regions are distributed at the three locations in the outer peripheral region. In another embodiment, the number of the terminal regions may be two or four or more as long as the load of the connector unit can be held through the resilient connection.

In the embodiments described above, the two vehicle-system connectors and the two signal-system connectors are provided, resulting in the four connector openings. In another embodiments, for example, the number of connector openings may be 1 to 3 or 5 or more, depending on the configuration, such as by unifying the vehicle-side connectors. In the embodiments described above, each of the vehicle-system connectors is the hybrid connector in which the power-system connector and the communication-system connector are integrated. In another embodiment, the hybrid connector may be modified as the power-system connector and the communication-system connector which are formed separately.

In the embodiments described above, the frame member is press-fitted into the motor case. In another embodiment, the connecting method for connecting between the frame member and the motor case may be other than the press-fitting. For example, the frame member and the motor case may be fixed together by, for example, screws or the like.

In the embodiments described above, the electric motor is the brushless motor having the two sets (two systems) of three-phase windings. In another embodiment, the number of systems of the motor windings is not limited to two, and may be one or three or more. The electric motor may also be a type other than the brushless motor.

In the embodiments described above, the drive device is applied to the electric power steering apparatus. In another embodiment, the drive device may be applied to in-vehicle apparatuses other than the electric power steering apparatus, or to apparatuses other than those used in the vehicle.

The above disclosure, i.e., “the plurality of connector terminals are arranged in a plurality of rows that are radially displaced from each other, wherein each of the plurality of rows includes one or more connector terminals among the plurality of connector terminals, and the one or more connector terminals in a radially inner one of the plurality of rows are circumferentially displaced relative to the one or more connector terminals in a radially outer one of the plurality of rows positioned on a radially outer side of the radially inner one of the plurality of rows” may be combined with each of the disclosures relating to the drive device.

The above disclosure, i.e., “each of the plurality of load-bearing portions is spaced away from a wiring pattern formed in a corresponding one of a plurality of through-holes of the circuit board, through which the plurality of connector terminals are respectively inserted, and each of the plurality of load-bearing portions contacts the circuit board via an electrical insulation layer” may be combined with each of the disclosures relating to the drive device.

The above disclosure, i.e., “the cover has: a first fixing portion, which is located on a radially outer side of the circuit board and is fixed to the frame member on the one side of the frame member opposite to the electric motor; and a second fixing portion, which is located on a radially outer side of the connector portion and is fixed to the base portion on one side of the base portion opposite to the electric motor” may be combined with each of the disclosures relating to the drive device.

The present disclosure is not limited to the embodiments described above and can be implemented in various forms without departing from the spirit of the present disclosure.

The present disclosure has been described with reference to the embodiments. However, the present disclosure is not limited to the above embodiments and the structures described therein. The present disclosure also includes various variations and variations within the equivalent range. Also, various combinations and forms, as well as other combinations and forms that include only one element, more, or less, are within the scope and ideology of the present disclosure.

What is claimed is:

1. A drive device comprising:
an electric motor;
a frame member that is located on one side of the electric motor in an axial direction;
a circuit board that is located on one side of the frame member opposite to the electric motor and is fixed to the frame member;
a connector unit that includes:
a base portion;
a connector portion, which is located on one side of the base portion opposite to the electric motor;
a plurality of terminal holding portions, which are formed integrally with the base portion and the connector portion in one-piece and are located on another side of the base portion where the electric motor is placed; and
a plurality of connector terminals, which project from the plurality of terminal holding portions, wherein the plurality of connector terminals resiliently contact and are thereby mechanically and electrically connected to the circuit board; and
a cover that is formed separately from the connector unit and receives the circuit board and the plurality of connector terminals in a state in which the connector portion is exposed outside the cover, wherein:
a plurality of load-bearing portions are formed on the frame member in at least one terminal region where the plurality of connector terminals are connected to the circuit board, and the plurality of load-bearing portions project toward and contact the circuit board.

2. The drive device according to claim 1, wherein:
a plurality of circuit-board fixing portions, to which the circuit board is fixed by a plurality of fastener members, are formed on the frame member; and
a height of each of the plurality of load-bearing portions is equal to a height of each of the plurality of circuit-board fixing portions.

3. The drive device according to claim 1, wherein:
a distal end portion of each of the plurality of connector terminals, which is inserted through the circuit board, is defined as a terminal distal end portion; and
each of the plurality of load-bearing portions is shaped in a ring form and surrounds an outer periphery of the terminal distal end portion of a corresponding one of the plurality of connector terminals.

4. The drive device according to claim 1, wherein:
a distal end portion of each of the plurality of connector terminals, which is inserted through the circuit board, is defined as a terminal distal end portion; and
each of the plurality of load-bearing portions is at least partially opened and thereby partially surrounds a corresponding one of a plurality of terminal groups, each of which includes two or more of the terminal distal end portions of the plurality of connector terminals.

5. The drive device according to claim 1, wherein:
a distal end portion of each of the plurality of connector terminals, which is inserted through the circuit board, is defined as a terminal distal end portion; and
each of the plurality of load-bearing portions is placed adjacent to the terminal distal end portion of a corresponding one of the plurality of connector terminals.

6. The drive device according to claim 1, wherein:
the plurality of connector terminals are arranged in a plurality of rows that are radially displaced from each other, wherein each of the plurality of rows includes one or more connector terminals among the plurality of connector terminals; and
the one or more connector terminals in a radially inner one of the plurality of rows are circumferentially displaced relative to the one or more connector terminals in a radially outer one of the plurality of rows positioned on a radially outer side of the radially inner one of the plurality of rows.

7. The drive device according to claim 1, wherein each of the plurality of load-bearing portions is spaced away from a wiring pattern formed in a corresponding one of a plurality of through-holes of the circuit board, through which the plurality of connector terminals are respectively inserted, and each of the plurality of load-bearing portions contacts the circuit board via an electrical insulation layer.

8. The drive device according to claim 1, wherein the cover has:
a first fixing portion, which is located on a radially outer side of the circuit board and is fixed to the frame member on the one side of the frame member opposite to the electric motor; and
a second fixing portion, which is located on a radially outer side of the connector portion and is fixed to the base portion on the one side of the base portion opposite to the electric motor.
